(19) United States
(12) Patent Application Publication
(10) Pub. No.: US 2012/0187389 A1
(43) Pub. Date: Jul. 26, 2012

(54) ORGANIC ELECTROLUMINESCENCE DEVICE, ORGANIC ELECTROLUMINESCENCE DISPLAY PANEL, AND METHOD OF MANUFACTURING ORGANIC ELECTROLUMINESCENCE DISPLAY PANEL

(76) Inventors: Ryo Shoda, Tokyo (JP); Eiichi Kitazume, Tokyo (JP)

(21) Appl. No.: 13/434,429

(22) Filed: Mar. 29, 2012

Related U.S. Application Data
(63) Continuation of application No. PCT/JP2010/065873, filed on Sep. 14, 2010.

(30) Foreign Application Priority Data
Sep. 30, 2009 (JP) 2009-226857

(51) Int. Cl. H01L 51/54; H01L 51/56

(52) U.S. Cl. 257/40; 438/46; 257/E51.018; 257/E51.026

(57) ABSTRACT

It is possible to obtain a display panel that can maintain efficiency while preventing defects caused by foreign substances in such a way that, after a hole injection layer formed so as to cover projections or foreign substances on electrodes is formed before partitioning pixels with barrier ribs, the barrier ribs are formed, and then a thin film is formed on the hole injection layer so that efficiency is not lowered by leaked current.

### CROSS REFERENCE TO RELATED APPLICATION

This application is a continuation of International Application No. PCT/JP2010/065873, the entire contents of which is incorporated herein by reference.

This application is based upon and claims the benefit of priority from the prior Japanese Patent Application No. 2009-226857, filed on Sep. 30, 2009, the entire content of which is incorporated herein by reference.

### BACKGROUND OF THE INVENTION

1. Field of the Invention

The present invention relates to an organic EL device and an image display device using such an organic EL device.

2. Background Art

An organic electroluminescence device (hereinafter, referred to as an organic EL device) is a device which has an organic light-emitting layer made of an organic light-emitting material formed between two opposite electrodes, and emits light by making current flow in the organic light-emitting layer, and the thickness of the organic layer is important in making a device with high efficiency and reliability. In addition, patterning to high definition is necessary for making a color display using the device.

Generally, as a substrate for displays, a substrate has been used which is formed in a barrier rib shape so that patterned photosensitive polyimide can partition sub-pixels. At this time, a barrier rib pattern is formed so as to cover the edge portion of a transparent electrode formed with an anode.

Next, as methods of forming a hole injection layer for injecting hole carriers, there are two kinds, which are a dry film formation method and a wet film formation method, and when the wet film formation method is used, a polythiophene derivative dispersed in water is generally used, but water-based ink is easily affected by a base and therefore very difficult to have uniformly coated. On the other hand, film formation by vapor deposition enables uniform full-face coating with ease.

As method of forming an organic light-emitting layer, there are two kinds of the dry film formation method and also the wet film formation method; when a vacuum vapor deposition is used which is the dry film formation that enables uniform film formation with ease, it is necessary to perform patterning using a mask of a fine pattern, and it is very difficult to perform fine patterning for a large substrate.

Thus, recently, a method of thin film formation with the wet film formation in which a polymeric material is dissolved in a solvent so as to make a coating fluid has been attempted. In layer structures in a case of forming a light-emitting medium layer that includes an organic light-emitting layer with the wet film formation method using such a coating fluid of a polymeric material, a two-layer structure is usual in which a hole transport layer and an organic light-emitting layer are laminated from the anode side. At this time, in order to attain a color panel, it is possible to coat the organic light-emitting layer with organic light-emitting ink obtained by dissolving or stabilizing and dispersing organic light-emitting materials having light-emitting colors of red (R), green (G), and blue (B) in a solvent (refer to JP-A-2001-93668 and JP-A-2001-155858).

A carrier injection layer (also referred to as a carrier transport layer) is formed between electrodes, in addition to the organic light-emitting layer. The carrier injection layer refers to a layer that is used for controlling an injection amount of electrons when the electrons are injected from an electrode to the organic light-emitting layer and for controlling an injection amount of holes when the holes are injected from the other electrode to the organic light-emitting layer, and a layer that is inserted between one of the electrodes and the organic light-emitting layer. As an electron injection layer, an organic substance having an electron transport property such as a metal complex of a quinolinol derivative or the like, a substance having a relatively small work function, for example, an alkaline earth metal of Ca, Ba, or the like is used, or there is also a case where plural layers having such functions are laminated. For the hole injection layer, TPD (triphenyleneamine-based derivative, refer to Japanese Patent No. 2916098), PEDOT:PSS (mixture of polythiophene and polystyrene sulfonate Japanese Patent No. 2851185), or an inorganic hole transport material (refer to JP-A-9-63771) are known to be used. In both cases, the layer is inserted between the electrode and the light-emitting layer aiming at enhancing light emission efficiency by controlling the injection amounts of electrons and holes.

Ideally, it is possible to derive performance by using different carrier injection layers for each of R, G, and B light-emitting layers, but a carrier transport layer is generally formed with a solid film for R, G, and B together due to the facts that procedures are added in amass production process and patterning with high definition is difficult.

FIG. 5 is a diagram showing a structure of a general organic EL device. First electrodes 102 are formed on a substrate 101 and a hole injection layer 104, an organic light-emitting layer 106, and a second electrode 107 are laminated on the first electrodes. Barrier ribs 103 are provided which partition pixels (sub-pixels). When the hole injection layer for injecting hole carriers is provided on the entire face of a light-emitting region that also includes the tops of the barrier ribs on the substrate where the sub-pixels are partitioned, there is a problem that light emission intensity is lowered without causing predetermined current to flow into the light-emitting region of pixels in such a way that leaking current, which flowed in the hole injection layer formed over the barrier ribs toward a non-light-emitting region of pixels in the direction inside the face of the hole injection layer, flows into the opposite electrode on the barrier ribs.

As means to solve the problem, making the carrier injection layer, which is formed on the entire face of the device, even thinner is considered to raise resistance in the inner face direction. However, there have been problems of minute projections of a base electrode film and insufficient coverage over unevenness on the surface caused by dust, and frequent occurrence of short circuit defects between the electrode and the opposite electrode as a result of using an ultrathin film, which had not been problems in the related art. General transparent electrodes used as an electrode mostly have a polycrystalline structure for achieving low resistance, and since there are minute projections having the size of several nm or larger, or projections having the size of dozens of nm or larger in parts, the short circuit defects easily occur as the thickness of constituting films becomes thinner. In addition, since there is a high probability that foreign substances entering after the formation of the injection layer penetrate the film and come into contact with electrodes as the film becomes thinner, the short circuit defects easily occur.

Thus, a manufacturing method of providing a barrier rib after the hole injection layer for injecting hole carriers is provided has been considered, but in a patterning process by photolithography accompanied by exposure and development, there have been problems that tolerance is lowered, such as cases where the thickness of a hole transport layer is reduced by developer, the film is degenerated, or the like, whereby the layer fails to fulfill the satisfactory function as a functioning layer. Particularly, an organic material has low tolerance, and molybdenum oxide, or the like in inorganic materials has low tolerance likewise. Based on the above reasons, it has been virtually impossible to form an inorganic hole injection layer which has an excellent carrier injection property before a barrier rib in the related art.

On the other hand, a manufacturing method has also been considered in which a hole injection layer is provided with an inorganic material having a reduced thickness and a low degree of degeneration in order to reduce leaking current, but there have been problems that the layer has insufficient hole injection and transport properties, and fails to fulfill the satisfactory function as a light-emitting medium layer.

It is intended to provide an organic EL device and a display device with high efficiency, a long life, and high luminance which can suppress leaking current that would lower light emission efficiency and can prevent defects caused by foreign substances by being provided with satisfactory hole injection and transport properties.
Patent document 1:JP-A-2001-93668
Patent document 2:JP-A-2001-155858
Patent document 3:JP-B-2916098
Patent document 4:JP-B-2851185
Patent document 5:JP-A-H9-63771

### SUMMARY OF THE INVENTION

According to a first aspect of the invention of a manufacturing method implemented to solve the above problems, there is provided a method of manufacturing an organic electroluminescence display panel including, on a substrate, first electrodes, a second electrode that is opposed to the first electrodes, barrier ribs partitioning the first electrodes, and a light-emitting medium layer that is sandwiched between the first electrodes and the second electrode and includes at least an organic light-emitting layer and a carrier injection layer that is formed between the first electrodes and the organic light-emitting layer, the method including forming a pattern of the first electrodes, forming, on the first electrodes, the carrier injection layer that includes a mixture of a hole transport material and a second metal compound, the hole transport material being a first metal compound and forming the barrier ribs so as to cover edge portions of the first electrodes of which the pattern is formed and cover at least part of the carrier injection layer.

Furthermore, a second aspect of the invention is that there is provided an organic electroluminescence device including, on a substrate, first electrodes, a second electrode that is opposed to the first electrodes, barrier ribs partitioning the first electrodes, and a light-emitting medium layer that is sandwiched between the first electrodes and the second electrode and includes at least an organic light-emitting layer and a carrier injection layer that is formed between the first electrodes and the organic light-emitting layer, wherein a plurality of the first electrodes are subjected to pattern formation on the substrate, the carrier injection layer is formed on the first electrodes and includes a mixture of a hole transport material and a second metal compound, the hole transport material being a first metal compound and the barrier ribs cover edge portions of the first electrodes that are subjected to pattern formation and cover a part of the carrier injection layer.

### BRIEF DESCRIPTION OF THE DRAWINGS

FIG. 1 is a descriptive cross-sectional diagram of an example of an organic EL device according to the invention.

FIG. 2 is a descriptive cross-sectional diagram of another example of the organic EL device according to the invention.

FIG. 3 is a descriptive cross-sectional diagram of a TFT substrate.

FIG. 4 is a schematic diagram of a relief printing device.

FIG. 5 is a descriptive cross-sectional diagram of an organic EL device of the related art.

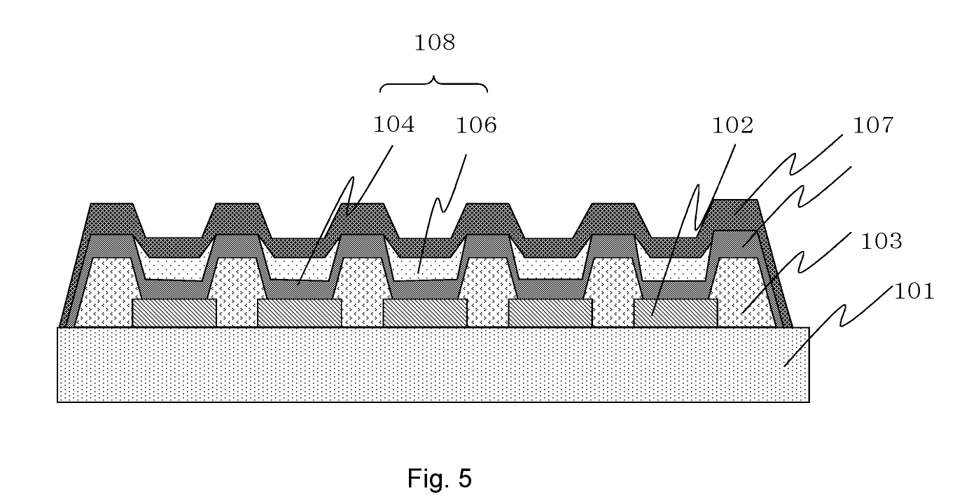

### DETAILED DESCRIPTION OF THE INVENTION

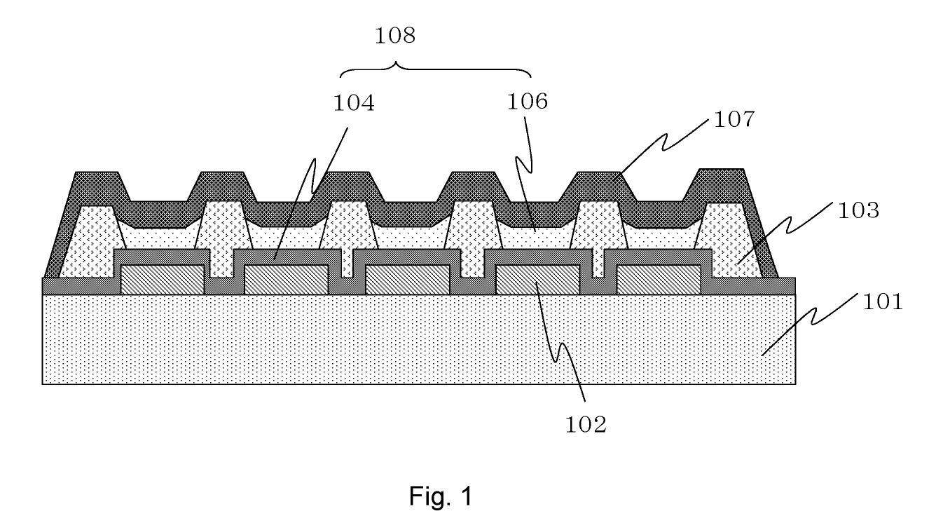

FIG. 1 shows a schematic diagram of an organic EL device as a first embodiment of the invention. The organic EL device of the invention includes layers (light-emitting medium layer 108) sandwiched between first electrodes 102 formed on a substrate 101 and a second electrode 107 formed as opposed thereto. The light-emitting medium layer includes an organic light-emitting layer 106 that contributes at least to light emission and a carrier injection layer 104 as a carrier injection layer for injecting electrons or holes. Furthermore, as the light-emitting medium layer 108, it is possible to laminate an electron injection layer and a hole blocking layer (interlayer) between the cathode and the light-emitting layer, a hole injection layer and an electron blocking layer (interlayer) 105 between the anode and the light-emitting layer, or the like, if necessary.

Furthermore, the organic EL device of the invention includes barrier ribs 103 for partitioning the organic light-emitting layer 106. By arranging the organic EL device by pixels (sub-pixels), it is possible to attain an image display device. It is possible to manufacture a full-color display panel by coloring the light-emitting layer 106 constituting each pixel with three colors of, for example, R, G, and B.

In the organic EL device of the invention, the carrier injection layer 104 is formed between the first electrodes 102 and the organic light-emitting layer 106, and furthermore, at least part of the carrier injection layer 104 is sandwiched between barrier ribs. In other words, the carrier injection layer is formed between the substrate and the barrier ribs. In the above configuration, since the carrier injection layer formed between the light-emitting layer 106 and the first electrodes 102 exposes only pixel portions that are light-emitting regions formed without the barrier ribs and thus does not contribute to current leakage to the opposite electrode, it is possible to set an arbitrary thickness.

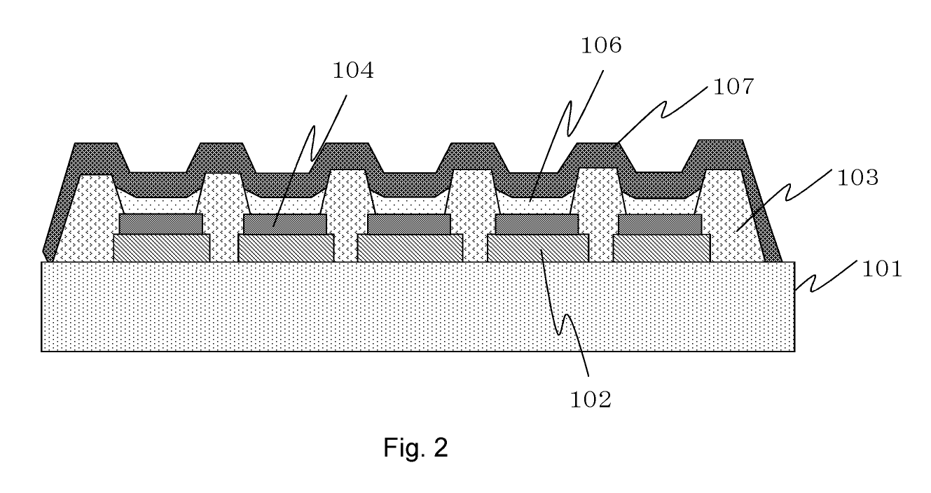

The carrier injection layer 104 is composed of a mixture of a hole transport material that is a first metal compound and a second metal compound, and may be continuously formed so as to cover the tops of the first electrodes and the entire surface of the substrate including the space between the tops of the first electrodes, that is, the entire face of the display region as shown in FIG. 1, and may be formed in a pattern so as to only cover the tops of the first electrodes as shown in FIG. 2. Only if at least the edge portions of the carrier injection layer are covered by the barrier ribs, does inconvenience such as short circuiting caused by concentration of an electric field due to unevenness of the edge portions not occur.

A hole transport material that is the first metal compound can be selected from transition metals having the thickness of 100 nm or thinner and transmittance of visual light wavelength region of 50% or higher, or oxides, fluorides, borides, and nitrides of Group III-B, but molybdenum oxide having an excellent hole injection property is more preferable.

As the second metal compound, transition metals, elements of Group III-B, or a compound thereof can be exemplified, but molybdenum dioxide, indium oxide, titanium oxide, iridium oxide, tantalum oxide, nickel oxide, tungsten oxide, vanadium oxide, stannous oxide, lead oxide, niobium oxide, aluminum oxide, copper oxide, manganese oxide, praseodymium oxide, chromium oxide, bismuth oxide, calcium oxide, barium oxide, cesium oxide, lithium fluoride, sodium fluoride, zinc selenide, zinc telluride, gallium nitride, gallium indium nitride, magnesium-silver, lithium-aluminum, and lithium-copper are more preferable in that the elements have high tolerance against water and developer used in forming a barrier rib, and also have properties of hole injection and transport, and electron injection and transport.

The manufacturing method of the carrier injection layer 104 can be arbitrarily selected from a method of performing co-deposition in a vacuum or a method of performing sputtering for the hole transport material that is the first metal compound and the second metal compound, and a method of performing sputtering for the mixture target of the hole transport material that is the first metal compound and the second metal compound, but taking process stability and convenience into consideration, the method of performing sputtering for the mixture target is more preferable.

By forming the carrier injection layer 104 of the hole transport material that is the first metal compound and the second metal compound in the configuration of the invention, it is possible to significantly suppress damage of the photolithography process of patterning the barrier ribs given to the surface of the carrier injection layer 104.

It is preferable that the thickness of the carrier injection layer be equal to or thicker than 20 nm and equal to and thinner than 100 nm. If the thickness is thinner than 20 nm, short circuit defects easily occur, and if the thickness exceeds 100 nm, current flowing to pixels becomes low due to high resistance.

Hereinafter, the configuration of the invention will be described in detail following a manufacturing process. As an example for describing the organic EL display device of the invention, an active-matrix drive type organic EL display device having the first electrodes 102 as the cathode and the second electrode 107 as the anode will be described. In this case, the first electrodes are formed as pixel electrodes in which pixels are partitioned by barrier ribs, and the second electrode is the opposite electrode formed on the entire surface of the device. In addition, the carrier injection layer 104 is set to be a hole injection layer having the hole transport property. The invention is not limited thereto, and the device may be a passive-matrix drive type in which each of electrodes is orthogonal to one another in, for example, a stripe shape. In addition, an organic EL device having the opposite structure in which the first electrodes are set to have the anode may be possible. In this case, the carrier injection layer is set to be an electron injection layer having the electron transport property.

### <Substrate>

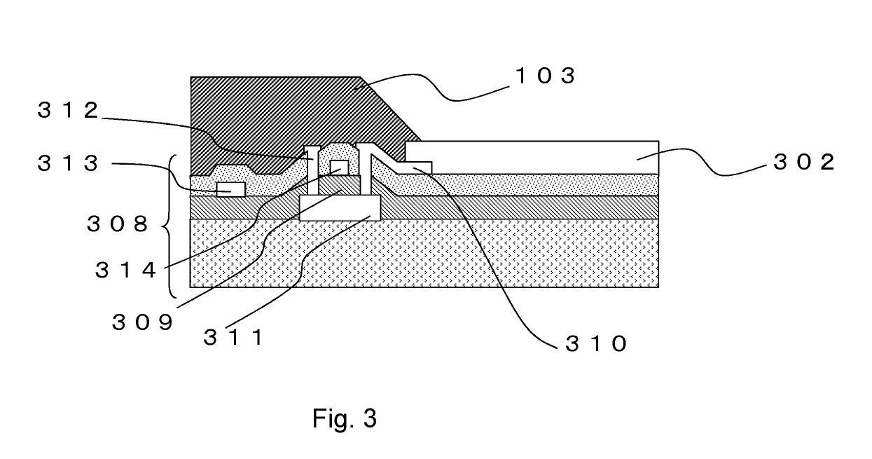

FIG. 3 shows an example of a TFT substrate with barrier ribs that can be used in the invention. A substrate (backplane) 308 used in the active-matrix drive type organic EL display device of the invention is provided with a thin-film transistor (TFT), pixel electrodes (first electrodes 102) of the organic EL display device, and the carrier injection layer 104, and the TFT and the pixel electrodes are electrically connected to each other.

The TFT and the active-matrix drive type organic EL display device configured above are supported by a support. As such a support, any materials can be used if the support has mechanical strength and an insulation property and excellent dimensional stability. It is possible to use, for example, glass, quartz, a plastic film or a sheet such as polypropylene, polyethersulfone, polycarbonate, a cycloolefin polymer, polyarylate, polyamide, polymethyl methacrylate, polyethylene terephthalate, polyethylene naphthalate, or the like, a light-transmissive base material obtained by laminating, onto the plastic film or the sheet, a metal oxide such as a silicon oxide, an aluminum oxide, or the like, a metal fluoride such as an aluminum fluoride, a magnesium fluoride, or the like, a metal nitride such as a silicon nitride, an aluminum nitride, or the like, a metal oxynitride such as a silicon oxynitride, or the like, or a polymeric resin film such as an acrylic resin, an epoxy resin, a silicon resin, a polyester resin, or the like, a non-light-transmissive base material such as a metal foil of aluminum, stainless steel, or the like, a sheet, a plate, materials obtained by laminating, onto the plastic film or the sheet, a metal film of aluminum, copper, nickel, stainless steel, or the like. The transmission property of the support may be selected according to from which face light extraction is to be performed. In order to avoid permeation of moisture into the organic EL display device, such a support made of the materials is preferably formed with an inorganic film, coated with a fluorine resin, or undergoes a damp proofing process or a hydrophobic process. Particularly, in order to avoid water entering the light-emitting medium layer, it is preferable to lower the moisture content and the gas permeation coefficient of the support.

As the thin-film transistor provided on the support, a known thin-film transistor can be used. Specifically, a thin-film transistor can be exemplified which is constituted mainly by an active layer on which source and drain regions and channel regions, a gate insulating film and a gate electrode. As the configuration of the thin-film transistor is not particularly limited thereto, and for example, a staggered type, an inversely staggered type, a top gate type, a bottom gate type, a coplanar type, and the like can be exemplified.

An active layer 311 is not particularly limited, and can be formed of an inorganic semiconductor material, for example, amorphous silicon, polycrystalline silicon, microcrystalline silicon, cadmium selenide, or the like, or an organic semiconductor material such as thiophene oligomer, poly(p-phenylenevinylene), or the like. Such an active layer can be formed by methods including, for example, a method in which amorphous silicon is laminated by plasma CVD and undergoes ion-doping; a method in which amorphous silicon is formed by LPCVD using SiH₄ gas, crystallized by a solid phase growth to obtain polysilicon, and ion-doping is performed by ion implantation; a method (low-temperature process) in which amorphous silicon is formed by the LPCVD using Si₂H₆ gas or by PECVD using SiH₄ gas, annealed by a laser beam such as excimer layer, or the like to crystallize the amorphous silicon and then obtain polysilicon, and ion-doping is performed by an ion-doping method; and a method (high-temperature process) in which polysilicon is laminated by reduced-pressure CVD or by LPCVD to form a gate insulating film by performing thermal oxidation at a temperature of 1000° C. or higher, a gate electrode 8 of n+ polysilicon is formed thereon, and then ion-doping is performed by ion implantation.

For the gate insulating film 309, a material that is generally used for a gate insulating film can be used, and for example, SiO₂, SiN, or SiON formed by PECVD, LPCVD, or the like, SiO₂ obtained by performing thermal oxidation for a polysilicon film, or the like can be exemplified.

For a gate electrode 314, a material that is generally used for a gate electrode can be used, and for example, a metal including aluminum, copper, silver, gold, or the like; a high melting point metal including titanium, tantalum, tungsten, or the like; polysilicon; a silicide of a high melting point metal; a polycide; and the like can be exemplified.

The thin-film transistor may have a single gate structure, a double gate structure, a multi-gate structure having three or more gate electrodes. In addition, the thin-film transistor may have an LDD structure, or an offset structure. Furthermore, two or more thin-film transistors may be arranged in one pixel.

In the display device of the invention, it is necessary for the thin-film transistor to be connected so as to function as a switching device of the organic EL display device, and a drain electrode 310 of the transistor is electrically connected to the pixel electrodes of the organic EL display device.

### <Pixel Electrode>

The pixel electrodes 102 are formed on the substrate, and patterning thereof is performed if necessary. In the invention, the pixel electrodes are partitioned by the barrier ribs and are pixel electrodes corresponding to each pixel. As materials of the pixel electrodes, any materials can be used including a metal composite oxide such as an ITO (indium-tin complex oxide), an indium-zinc complex oxide, a zinc-aluminum complex oxide, or the like, a metal material such as gold, platinum, or the like, a single or a laminated particle-dispersed film obtained by dispersing particles of the metal oxide or a metal material in an epoxy resin, an acrylic resin, or the like. When the pixel electrodes are set to be the anode, it is preferable to select a material having a high work function such as an ITO. In the case of a structure in which light is extracted from a lower part, which is a so-called bottom emission structure, it is necessary to select a material having a transmissive property. A metal material such as copper, aluminum, or the like may also be used as a secondary electrode, if necessary, in order to lower wiring resistance of the pixel electrodes. As a method of forming the pixel electrodes, a dry deposition method such as a resistance heating vapor deposition method, an electron beam deposition method, a reactive deposition method, an ion plating method, a sputtering method, or a wet deposition method such as a gravure printing method, a screen printing method, or the like can be used depending on the material. As a method of patterning the pixel electrodes, a known pattering method such as a mask deposition method, a photolithography method, a wet etching method, a dry etching method, or the like can be used depending on the material and the deposition method. When a substrate that is formed with a TFT is used, such a device is formed so as to attain conduction to pixels in a lower layer. In the case of a top emission structure, it is preferable to use a metal material such as aluminum, silver, or the like in the pixel electrodes in order to reflect light from the light-emitting layer, or to use an electrode obtained by laminating an ITO on the metal material.

### <Carrier Injection Layer>

The carrier injection layer 104 of the invention is patterned so as to cover the first electrodes or formed so as to cover the entire face of the substrate and the first electrodes. The carrier injection layer 104 is composed of a mixture of the hole transport material that is a first metal compound and a second metal compound, and as the hole transport material that is a first metal compound, a transition metals having the thickness of 100 nm or thinner and transmittance of visual light wavelength region of 50% or higher, or oxides, fluorides, borides, and nitrides of Group III-B can be selected, but molybdenum oxide having an excellent hole injection property (MoOx having MoO₃ as the main component) is more preferable.

As the second metal compound, transition metals, elements of Group III-B, or a compound thereof can be exemplified, but molybdenum dioxide, indium oxide, titanium oxide, iridium oxide, tantalum oxide, nickel oxide, tungsten oxide, vanadium oxide, stannous oxide, lead oxide, niobium oxide, aluminum oxide, copper oxide, manganese oxide, praseodymium oxide, chromium oxide, bismuth oxide, calcium oxide, barium oxide, cesium oxide, lithium fluoride, sodium fluoride, zinc selenide, zinc telluride, gallium nitride, gallium indium nitride, magnesium-silver, lithium-aluminum, and lithium-copper are more preferable in that the elements have high tolerance against water and developer used in forming a barrier rib, and also have properties of hole injection and transport, and electron injection and transport, and it is possible that a mixture of any or a few of the elements be mixed into the first metal compound so as to be used as the material of the carrier injection layer.

For the second metal compound, a material is selected which has an insoluble property and tolerance particularly against a developer in a barrier rib formation process as described later. As a ratio of the first metal compound and the second metal compound, the ratio of the second metal compound to the sum of the amount of material of the hole transport material that is the first metal compound and the amount of material of the second metal compound is preferably 20 mol % or higher and 75 mol % or lower. If the ratio is less than 20 mol %, there is a possibility that tolerance against developer that is an effect of the second metal compound may not be sufficiently exhibited, and on the contrary, if the ratio exceeds 75%, the carrier injection property deteriorates, leading to a decrease in light emission efficiency. Furthermore, the composition of a film as described above can be computed using, for example, XPS. The carrier injection layer of the invention exhibits tolerance against developer due to the second metal compound, but the thickness of the carrier injection layer slightly decreases due to the developer depending on the ratio of the second metal compound.

The thickness of the carrier injection layer is preferably 20 nm or thicker and 100 nm or thinner. If the thickness is thinner than 20 nm, short circuit defects easily occur, and if the thickness is thicker than 100 nm, current flowing to pixels becomes low due to high resistance.

Herein, at least part of the carrier injection layer of the invention is covered by the barrier ribs to be described later, and the thickness of the carrier injection layer in the parts of the barrier ribs formed by a photolithography process is the same as that when the carrier injection layer is formed. However, there is a case where the thickness of part of the carrier injection layer not covered by the barrier ribs slightly decreases due to the developer of a barrier rib formation process depending on the amount of material of the second metal compound in the carrier injection layer or the type of the developer to be used. For this reason, it is desired to form the carrier injection layer considering a decrease in the thickness of the carrier injection layer by the barrier rib formation process so that the thickness of the carrier injection layer formed in the parts where the barrier ribs are not formed, in other words, in the parts that serve as the light-emitting regions on the first electrodes become 20 nm or thicker and 100 nm or thinner after the barrier rib formation process, depending on the amount of material of the second metal compound in the carrier injection layer or the type of the developer to be used.

Furthermore, since the thickness does not decrease due to the developer if the amount of material of the second metal compound in the carrier injection layer is sufficient, the thickness of the carrier injection layer becomes uniform regardless of the formation of the barrier ribs.

As a method of producing the carrier injection layer 104, any one of a method of performing co-deposition in a vacuum or a method of performing sputtering for the hole transport material that is the first metal compound and the second metal compound, and a method of sputtering the mixture target composed of the hole transport material that is the first metal compound and the second metal compound can be arbitrarily selected, but the method of sputtering the mixture target is preferable, considering process stability and convenience. In addition, patterning may be performed for each pixel electrode in such away that a mask is formed after being brought into tight contact with a substrate, and patterned.

### <Barrier Rib>

The barrier ribs 103 of the invention are formed so as to partition the light-emitting area corresponding to the pixels. It is preferable that the barrier ribs be formed so as to cover the edge portions of the pixel electrodes 102 (refer to FIG. 2). When the carrier injection layer 104 is formed over the entire face of the light-emitting region between and on the pixel electrodes, that is, the entire face of the display region on the substrate, the barrier ribs are formed so as to cover the carrier injection layer 104 positioned between the pixel electrodes and the edge portions of the pixel electrodes. In addition, when the carrier injection layer is patterned so as to cover only the pixel electrodes 102, the barrier ribs come also to cover the edge portions of the carrier injection layer. With the configuration, it is possible to prevent short circuiting caused by unevenness on the light-emitting layer formed face. Generally, the pixel electrodes 102 are formed for each pixel (sub-pixel) in an active-matrix drive type display device, and each pixel are designed to occupy a large area as possible as it can, and thus, the most preferable shape of the barrier ribs formed so as to cover the edge portions of the pixel electrodes is basically set to be a grid shape that can partition each pixel electrode in the shortest distance. In addition, as a cross-sectional shape of the barrier ribs, a forwardly tapered shape, a reversely tapered shape, a semicircular shape, or the like may be possible.

As a method of forming the barrier ribs, a known method in the related art can be used. Specifically, the barrier ribs are formed in such a way that a photosensitive resin material such as polyimide, or the like is made into a film on the entire face of the substrate by spin coating, slit coating, deep coating, or the like, the pattern of the barrier ribs is exposed using a mask, the resultant product is developed with an alkaline developer such as TMAH (tetramethylammonium hydroxide), or the like, and rinsed with ultrapure water, or the like, the water is pushed away with an air knife, or the like so as to take out unnecessary resins, and water in the resultant product is dried in an oven. The photosensitive resin material may be a positive resist or a negative resist, but is desired to have an insulation property. A water repellent may be added thereto if necessary, or liquid repellency against ink can be given thereto after being formed by being irradiated with plasma or UV. The height of the barrier ribs is preferably 0.1 μm to 10 μm, and more preferably about 0.5 μm to 2 μm. If the barrier ribs are excessively high, it disturbs the formation and sealing of the opposite electrode, and if the barrier ribs are excessively low, the barrier ribs are not able to cover the edge portions of the pixel electrodes, or colors of adjacent pixels are mixed together when the light-emitting medium layer is formed.

Furthermore, the barrier rib may be configured to be a multi-stage barrier rib with, for example, a two-layered structure. In this case, a barrier rib of the first stage is formed so as to cover the edge portions of a first electrode on a TFT substrate, and can have a reversely tapered shape, a forwardly tapered shape, or the like. As a material to be used, for example, an inorganic oxide such as a silicon oxide, a tin oxide, an aluminum oxide, a titanium oxide, or the like, an inorganic nitride such as a silicon nitride, a titanium nitride, a molybdenum nitride, or the like, an inorganic nitride oxide film such as a silicon nitride oxide can be exemplified, but the material is not limited thereto. Among the materials for the inorganic insulating film, the most appropriate are silicon nitride, silicon oxide, and titanium oxide. Such materials can be used in the formation using a dry coating method represented by the sputtering method, the plasma CVD method, and the resistance heating vapor deposition. In addition, an inorganic insulating film may be formed after coating ink that contains an inorganic insulation material using a known coating method suing a spin coater, a bar coater, a roll coater, a die coater, a gravure coater, or the like, and then eliminating a solvent in a burning process such as air drying, heating drying, or the like. Next, a pattern is formed by coating a photosensitive resin on the inorganic insulating film, exposing, and developing it. As a photosensitive resin, any one of a positive resist and a negative resist may be used. A resist on the market may also be used. As a process of forming a pattern, a method for obtaining a predetermined pattern using the photolithography method can be exemplified. Furthermore, in the invention, the method is not limited thereto, and other methods may also be used. A surface processing such as plasma irradiation, UV irradiation, or the like onto the inorganic insulating film may also be performed, if necessary. The thickness of the barrier rib of the first stage is preferably 50 nm or thicker and 1000 nm or thinner in order to secure the insulation property as there is a material having conductivity according to the thickness, for example, a silicon oxide. Furthermore, is the thickness is 150 nm or thicker, the barrier rib can be appropriately used. It is possible to form a barrier rib of the second stage made of a photosensitive resin with the above-described methods after the barrier rib of the first stage is formed.

When the barrier rib is set as the multi-stage barrier rib, at least the barrier rib of the first stage is formed so as to cover the edge portions of the first electrodes. In addition, the carrier injection layer 104 is formed so as to cover, for example, the entire face on the TFT substrate or the tops of the first electrodes and the barrier rib of the first stage after the formation of the barrier rib of the first stage, and then, the barrier rib of the second stage is formed so as to cover as least part of the carrier injection layer. Furthermore, by setting tolerance of the carrier injection layer 104 against the developer to be higher by raising the ratio of the amount of material of the second metal compound in the carrier injection layer 104, it is possible to suppress the problem of a decrease in the thickness or degeneration of the carrier injection layer caused by the developer or ultrapure water even after performing the photolithography process plural times to form the multi-stage barrier rib after the carrier injection layer is formed on the entire face on the first electrodes or the substrate, and therefore, the carrier injection layer may be formed on the TFT substrate prior to the barrier rib of the first stage even in the case of the multi-stage barrier rib.

According to the invention, it is possible to maintain the surface state of the carrier injection layer against the developer or ultrapure water in the barrier rib formation process. Molybdenum oxide is an excellent material for the carrier injection layer, but since the material is soluble in a developer or ultrapure water, there is a problem that the thickness of the layer extremely decreases after the photolithography process if the layer is formed solely of the material. In the invention, by using a carrier injection layer in which a second metal compound is further mixed with a material with a good carrier injection property as the carrier injection layer, it is possible to suppress damage or degeneration thereof in the barrier rib formation process even when the layer is formed before the formation of the barrier rib.

As characteristics of the carrier injection layer, it is particularly desirable to have high tolerance against a developer to be used in the formation of the barrier rib, and specifically, it is preferable that, when a substrate formed with the carrier injection layer is immersed in a developer to be used for three hours, the layer show 10% or less change in the average thickness thereof before and after immersion. If more change in thickness is shown, there is a high probability of having short circuit defects in a device. When the thickness of the carrier injection layer decreases due to the barrier rib formation process, there is a difference between the thickness of a portion of the carrier injection layer 104 covered by the barrier rib and the thickness of a portion thereof not covered by the barrier rib after the formation of the barrier rib, and the portion without the barrier rib shows a decrease in the thickness, and therefore, the portion of the carrier injection layer covered by the barrier rib has a thicker thickness.

For this reason, when the composition of the first metal compound and the second metal compound of the carrier injection layer is set so that a change in the average thickness before and after immersion is 10% or less, a difference between the thickness of the carrier injection layer that is covered by the barrier rib, in other words, in the lower part of the barrier rib and the thickness of the portion of the carrier injection layer without the barrier rib becomes 10% or less, and since the carrier injection layer is formed in consideration of the decrease in the thickness caused by the developer so that the thickness keeps the necessary level after the barrier rib formation process, the thickness of the portion of the carrier injection layer covered by the barrier rib is set to be 100% or thicker and 110% or thinner of the necessary thickness as the carrier injection layer.

### <Interlayer>

After the formation of the barrier rib, it is possible to form an interlayer as a layer between a light-emitting layer and an electrode. It is preferable to provide an interlayer as an electron blocking layer between an organic light-emitting layer and a carrier injection layer. The light emission life of an organic EL device can be enhanced. After forming the carrier injection layer, the interlayer can be laminated on the carrier injection layer. Generally, the interlayer is formed so as to cover the carrier injection layer, but the interlayer may be formed by patterning if necessary.

As a material of the interlayer, among organic materials, a polymer including an aromatic amine such as polyvinylcarbazole, a polyarylene derivative having an aromatic amine in a derivative, a side chain, the main chain of polyvinylcarbazole, an arylamine derivative, a triphenyldiamine derivative, or the like is exemplified. In addition, as an inorganic material, an inorganic compound containing a transition metal oxide such as Cu₂O, Cr₂O₃, Mn₂O₃, NiO, CoO, Pr₂O₃, Ag₂O, MoO₂, ZnO, TiO₂, V₂O₅, Nb₂O₅, Ta₂O₅, MoO₃, WO₃, MnO₂, or the like and one or more kinds of a nitride, or a sulfide thereof is exemplified. Furthermore, in the invention, a material is not limited to the above, and other materials may be used.

An organic material of the interlayer is dissolved or stably dispersed in a solvent, and used as an organic interlayer ink (liquid material of an organic interlayer). As a solvent in which a material of the organic interlayer is to be dissolved or dispersed, a single or mixed solvent of toluene, xylene, acetone, anisole, methyl ethyl ketone, methyl isobutyl ketone, cyclohexanone, or the like is used. Among these, an aromatic organic solvent such as toluene, xylene, or anisole is appropriately used in terms of solubility of the organic interlayer material. In addition, a surfactant, an antioxidant, a viscosity modifier, an ultraviolet absorber, or the like may be added to organic interlayer ink, if necessary.

Among the materials of the interlayer, it is preferable to select a material having the work function equal to or higher than that of the carrier injection layer, and furthermore, to select a material having the work function equal to or lower than that of the organic light-emitting layer 106. The reason is that an unnecessary injection barrier is not formed when carriers are injected from the carrier injection layer to the organic light-emitting layer 106. In addition, since there is an effect of confining electric charges that have not contributed to light emission from the organic light-emitting layer 106, it is preferable to employ a material having a band gap of 3.0 eV or higher, and more preferable to employ a material having a band gap of 3.5 eV or higher.

As a method of forming the interlayer, a known film formation method can be used, which includes a dry film formation method such as a resistance heating vapor deposition method, an electron beam deposition method, a reactive deposition method, an ion plating method, a sputtering method or the like, or a wet deposition method such as an ink jet printing method, a relief printing method, a gravure printing method, a screen printing method, or the like, depending on the material. Furthermore, in the invention, the method is not limited to the above, and other method may be used.

### <Organic Light-Emitting Layer>

After the formation of the interlayer, the organic light-emitting layer 106 is formed. The organic light-emitting layer emits light by running current therein, and when display light discharged from the organic light-emitting layer 106 is a plain color, the layer is formed so as to cover the interlayer 105, but in the case of obtaining display light having multiple colors, the layer can be appropriately used after being patterned, if necessary.

As an organic light-emitting material to form the organic light-emitting layer 106, for example, a material obtained by dispersing a coumarin-based, perylene-based, pyran-based, anthrone-based, porphyrin-based, quinacridone-based, N,N′-dialkyl-substituted quinacridone-based, naphthalimide-based, N,N′-diryl-substituted pyrrolo-pyrrole-based, iridium complex-based light-emitting pigment, or the like in a polymer such as polystyrene, polymethyl methacrylate, polyvinyl carbazole, or the like, or a polyarylene-based, polyarylene vinyl-based, or polyfluorene-based polymeric material is exemplified, but the material of the invention is not limited to the above.

When the organic light-emitting layer is formed by an application method, such an organic light-emitting material is applied after being dissolved or stably dispersed in a solvent so as to be used as organic light-emitting ink. As a solvent in which the organic light-emitting material is to be dissolved or dispersed, a single or mixed solvent of toluene, xylene, acetone, anisole, methyl ethyl ketone, methyl isobutyl ketone, cyclohexanone, or the like is exemplified. Among these, an aromatic organic solvent such as toluene, xylene, or anisole is appropriate in terms of solubility of the organic light-emitting material. In addition, a surfactant, an antioxidant, a viscosity modifier, an ultraviolet absorber, or the like may be added to organic light-emitting ink, if necessary.

In addition to the above-described polymeric materials, a small molecule-based light-emitting material can be used which includes a 9,10-diarylanthracene derivative, pyrene, coronene, perylene, rubrene, 1,1,4,4-tetraphenylbutadiene, a tris(8-quinolate)aluminum complex, a tris(4-methyl-8-quinolate)aluminum complex, a bis(8-quinolate)zinc complex, a tris(4-methyl-5-trifluoromethyl-8-quinolate)aluminum complex, a tris(4-methyl-5-cyano-8-quinolate aluminum complex, a bis(2-methyl-5-trifluoromethyl-8-quinolinolate)[4-(4-cyano phenyl)phenolate]aluminum complex, a bis(2-methyl-5-cyano-8-quinolinolate) [4-(4-cyanophenyl) phenolate]aluminum complex, a tris(8-quinolinolate)scandium complex, a bis[8-(paratosyl)aminoquinoline]zinc complex and a cadmium complex, a 1,2,3,4-tetraphenylcyclopentadiene, a poly-2,5-diheptyloxy-para-phenylenevinylene, or the like.

### <Formation Method of Light-Emitting Medium Layer>

As a formation method of the organic light-emitting layer 106, a known film formation method can be used, which includes a dry film formation method such as a resistance heating vapor deposition method, an electron beam deposition method, a reactive deposition method, an ion plating method, a sputtering method or the like, or an application method such as an ink jet printing method, a relief printing method, a gravure printing method, a screen printing method, or the like, depending on the material, and when the light-emitting medium layer is formed by an application method, and particularly when the light-emitting layer is coated in each light-emitting color using organic light-emitting ink obtained by dissolving or stably dispersing an organic light-emitting material in a solvent, the relief printing method in which ink is transferred between the barrier ribs for patterning is appropriate.

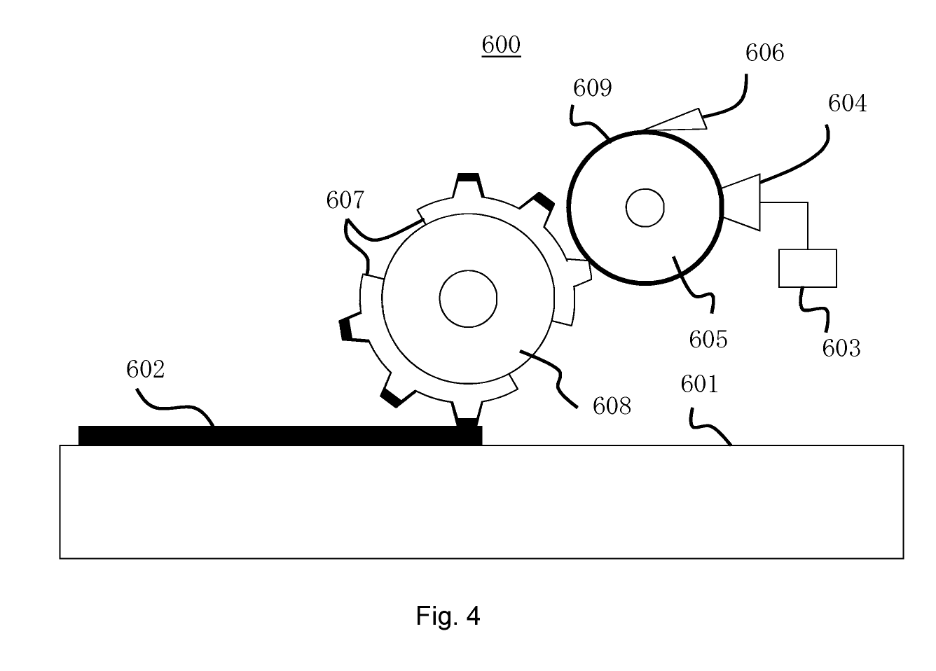

FIG. 4 shows a schematic diagram of a relief printer 600 when pattern printing is performed with organic light-emitting ink composed of an organic light-emitting material on a print target substrate 602 on which pixel electrodes, a hole injection layer, and an interlayer are formed. The printing device includes an ink tank 603, an ink chamber 604, an anilox roller 605, and a plate cylinder 608 mounted with a plate 607 having reliefs. The ink tank 603 retains organic light-emitting ink diluted in a solvent, and the ink chamber 604 is a place where the organic light-emitting ink is sent from the ink tank. The anilox roller 605 abuts the ink supply portion of the ink chamber 604 and is instructed so as to be rotatable.

According to rotation of the anilox roller 605, an ink layer 609 of organic light-emitting ink supplied to the surface of the anilox roller is formed in a uniform thickness. Ink of the ink layer is transferred to convex portions of the plate 607 mounted on the plate cylinder 608 that is rotatably driven close to the anilox roller. The print target substrate 602 is installed on a stage 601, ink on the convex portions of the plate 607 is printed onto the print target substrate 602 to form an organic light-emitting layer on the print target substrate after passing through a drying process if necessary. Ink supply means to the anilox roller is not limited to the ink chamber, and a coating method using a die coater, a slit coater, or the like may be used. In addition, it is desirable to use a doctor 606 such as a doctor roller, a doctor blade, or the like in order to make ink supplied onto the surface of the anilox roller uniform, but when a die coater is used as ink supply means, the doctor 606 may not be provided.

When other light-emitting medium layer is coated with ink, the same formation method as above can be used.

### <Electron Injection Layer>

After the organic light-emitting layer 106 is formed, it is possible to form a hole blocking layer, an electron injection layer, or the like. These functional layers can be arbitrarily selected based on the size of an organic EL display panel, or the like. As a material to be used in the hole blocking layer and the electron injection layer, a material that is generally used as an electron transport material is possible, and such layers can be formed by the vacuum deposition method using a small molecule-based material including a triazole-based, an oxazole-based, an oxadiazole-based, a silole-based, a boron-based material, or the like, a salt or an oxide of an alkali metal such as a lithium fluoride or a lithium oxide or an alkaline earth metal, or the like. In addition, it is possible to form the layers by a printing method using, as an electron injection application liquid, the electron transport materials and by dissolving the electron transport materials in a polymer such as polystyrene, polymethyl methacrylate, polyvinyl carbazole or the like, and then dissolving or dispersing the resultant product in a single solvent or a mixed solvent of toluene, xylene, acetone, methyl ethyl ketone, methyl isobutyl ketone, cyclohexanone, methanol, ethanol, isopropyl alcohol, ethyl acetate, butyl acetate, water, and the like.

### <Opposite Electrode>

Next, the opposite electrode 107 is formed. When the opposite electrode is set to be the cathode, a material having high electron injection efficiency to the light-emitting layer 106 and a low work function is used. Specifically, a single metal such as Mg, Al, Yb, or the like may be used, or a material may be used which is obtained by putting 1 nm of a compound such as an oxide or a fluoride of Li or Na on the interface abutting to the light-emitting medium layer and then laminating Al or Cu that has high stability and conductivity thereon. Alternatively, in order to make electron injection efficiency and stability compatible, an alloy system of one or more kinds of metal having a low work function such as Li, Mg, Ca, Ba, Sr, La, Ce, Er, Eu, Sc, Y, Yb, or the like and a stable metal element such as Ag, Al, Cu, or the like may be used. Specifically, an alloy such as MgAg, AlLi, CuLi, or the like can be used.

As a method of forming the opposite electrode 107, a resistance heating vapor deposition method, an electron beam deposition method, a reactive deposition method, an ion plating method, or a sputtering method cab be used according to the material.

### <Sealing Body>

An organic EL display device can be caused to emit light by placing a light-emitting material between electrodes and making current flow therein, but since such an organic light-emitting material easily deteriorates due to moisture and oxygen in the air, a sealing body is generally provided in order to block outside influence. The sealing body can be produced by, for example, providing a resin layer on a sealing material.

For the sealing material, a base material having low permeability to moisture and oxygen is necessary. In addition, as an example of the material, ceramics such as alumina, silicon nitride, boron nitride, or the like, glass such as alkali-free glass, alkali glass, or the like, quartz, a moisture-resistant film, or the like can be exemplified. As examples of the moisture-resistance film, there are a film formed by performing a CVD method for SiOx on both faces of a plastic base material, a film with low permeability, a film with water absorbability, a polymeric film coated with a water absorbent, and the like, and the water vapor transmittance of the water-resistant film is preferably 10⁻⁶ g/m²/day or lower.

As an example of the material of the resin layer, a photo-curable adhesive resin composed of an epoxy-based resin, an acryl-based resin, a silicone resin, or the like, a thermally-curable adhesive resin, an acryl-based resin such as a two-liquid-curable adhesive resin, an ethylene ethyl acrylate (EEA) polymer, or the like, a vinyl-based resin such as ethylene vinyl acetate (EVA), or the like, a thermoplastic resin such as polyamide, a synthetic rubber, or the like, or a thermoplastic adhesive resin such as an acid denaturation object of polyethylene or polypropylene can be exemplified. As an example of a method for forming the resin layer on the sealing body, a solvent solution method, an extrusion lamination method, a melt/hot-melt method, a calender method, a nozzle coating method, a screen printing method, a vacuum laminating method, a thermal roll laminating method, or the like can be exemplified. A material having a moisture absorbing property or an oxygen absorbing property can be included therein if necessary. The thickness of the resin layer formed on the sealing material is arbitrarily determined depending on the size and shape of the organic EL display device to be sealed, but preferably 5 to 500 μm. Furthermore, herein, it is possible to directly form the resin layer formed on the sealing material in the side of the organic EL display device.

Finally, bonding of the organic EL display device and the sealing body is performed in a sealing chamber. The sealing body is set to have a two-layer structure with the sealing material and the resin layer, and when a thermoplastic resin is used in the resin layer, it is preferable only to perform pressing with a heated roller. When a thermally-curable adhesive resin is used, it is preferable to perform pressing with the heated roller, and to perform heating and curing at a curing temperature. When a photo-curing adhesive resin is used, curing can be performed by performing pressing with a roller and then irradiation of light.

By forming the hole injection layer so as to cover projections or foreign substances on the electrode before partitioning pixels with barrier ribs and forming the hole injection layer through mixture of a hole transport material that is a first metal compound and a second metal compound, it is possible to obtain an organic EL device and a display panel with high efficiency, a long life, and high luminance which can suppress leaking current that would lower light emission efficiency and can prevent defects caused by foreign substances by being provided with satisfactory hole injection and transport properties without a thickness decrease or degeneration of the hole injection layer resulting from the formation of the barrier ribs.

### EXAMPLE

### Example 1

Hereinafter, examples of the invention will be described.

As a substrate, an active-matrix substrate was used which is provided with a thin-film transistor that is provided on a support and functions as a switching element and pixel electrodes formed thereon. The size of the substrate was 200 mm×200 mm, and a display having 5 inches as the diagonal length and 320×240 of pixels was arranged in the center thereof. An extraction electrode and a contact portion were formed at the edge of the substrate.

The substrate was set on a sputtering film formation device on which a target was installed, masking was performed so as not to form a film on the extraction electrode or the contact portion, and a carrier injection layer was formed on a display region.

At that time, a mixture target of molybdenum and titanium of which the concentration of titanium was 25 mass % (40 mol %) was used. The sputtering condition was a pressure of 1 Pa and an electric power of 1 kW, and the flow ratio of oxygen to argon gas was 30%. The thickness thereof was set to 50 nm. As a result of measuring the composition of the film formed by XPS, the ratio of a titanium oxide to the amount of material of the whole film was 27 mol %.

After that, barrier ribs were formed so as to cover the edge portions of the pixel electrodes and to partition pixels provided on the substrate. In order to form the barrier ribs, after a positive resist ZWD6216-6 made by Zeon Corporation was formed on the entire face of the substrate so as to have a thickness of 2 μm using a spin coater, the pattern of the barrier ribs was exposed by the mask, development was performed using a developer of NMD3 (2.38% of TMAH) made by Tokyo Ohka Kogyo Co., Ltd., and the developer was rinsed using ultrapure water. The resultant product was heated at 100° C. in an oven in order to dry the water. As a result, the barrier ribs having a width of 40 μm were formed by photolithography. Accordingly, a pixel area with 960×240 dots of sub-pixels and 0.12 mm×0.36 mm pitches was partitioned.

As a result of measuring several spots of the thickness of the carrier transport layer after the photolithography, the thickness was 40 nm to 45 nm.

After that, the substrate was set in a printer using ink in which a polyvinylcarbazole derivative that is an interlayer material is dissolved in toluene so as to have the concentration of 0.5%, and printing was performed by a relief printing method after the line pattern of the substrate was aligned right on the pixel electrodes interposed in insulation layers. At that time, an anilox roller of 300-line/inch and a photosensitive resin plate were used. The thickness of the interlayer after printing and drying was 10 nm.

Next, the substrate was set in the printer using organic light-emitting ink in which a polyphenylene vinylene derivative that is an organic light-emitting material was dissolved in toluene so as to have the concentration of 1%, and printing was performed by the relief printing method after the line pattern of the substrate was aligned right on the pixel electrodes interposed in the insulation layers. At that time, an anilox roller of 150-line/inch and a photosensitive resin plate corresponding to the pitch of pixels were used. The thickness of the organic light-emitting layer after printing and drying was 80 nm. The process repeated three times, and organic light-emitting layers corresponding to light emission colors of R (red), G (green), and B (blue) were formed in each pixel.

After that, as an electron injection layer, a calcium film was formed with the thickness of 10 nm by the vacuum vapor deposition method, and then, an aluminum film as the opposite electrode was formed with the thickness of 150 nm.

Then, a glass plate as a sealing material was placed so as to cover the whole light-emitting region, and sealing was performed by thermally curing an adhesive at about 90° C. for one hour. As a result of driving the active-matrix drive type organic EL display device obtained as above, favorable driving could be performed.

### Example 2

A mixture target of titanium and molybdenum in which the concentration of the titanium was 35 mass % (52 mol %) was used to the target of Example 1, and other factors were same as those of Example 1. As a result of measuring the film composition of a carrier transport layer formed by XPS, the ratio of a titanium oxide to the amount of material of the whole film was 35 mol %.

As a result of measuring several spots of the thickness of the carrier transport layer after photolithography, the thickness was 45 nm to 50 nm.

After driving an active-matrix drive type organic EL display device obtained as above, favorable driving could be performed.

### Example 3

A mixture target of titanium and molybdenum in which the concentration of the titanium was 50 mass % (67 mol %) was used to the target of Example 1, and other factors were same as those of Example 1. As a result of measuring the film composition of a carrier transport layer formed by XPS, the ratio of a titanium oxide to the amount of material of the whole film was 52 mol %.

As a result of measuring several spots of the thickness of the carrier transport layer after photolithography, the thickness was 50 nm.

After driving an active-matrix drive type organic EL display device obtained as above, favorable driving could be performed.

### Comparative Example 1

A molybdenum target was used to the target of Example 1, and other factors were the same as those of Example 1.

As a result of measuring several spots of the thickness of a carrier transport layer after photolithography, the thickness was 0 nm to 5 nm, which virtually disappeared.

After an active-matrix drive type organic EL display device obtained as above was driven, light emission efficiency was remarkably lowered in a region that was not able to be measured due to flickering caused by short circuiting and even in pixels that barely emitted light.

### Comparative Example 2

A mixture target of titanium and molybdenum in which the concentration of the titanium was 17 mass % (30 mol %) was used to the target of Example 1, and other factors were same as those of Example 1. As a result of measuring the film composition of a carrier transport layer formed by XPS, the ratio of a titanium oxide to the amount of material of the whole film was 16 mol %.

As a result of measuring several spots of the thickness of the carrier transport layer after photolithography, the thickness was 10 nm to 18 nm.

After an active-matrix drive type organic EL display device obtained as above was driven, many pixels could not be measured due to flickering caused by short circuiting, and light emission efficiency was remarkably lowered even in a pixel that emitted light.

### Comparative Example 3

A mixture target of titanium and molybdenum in which the concentration of the titanium was 75 mass % (85 mol %) was used to the target of Example 1, and other factors were same as those of Example 1. As a result of measuring the film composition of a carrier transport layer formed by XPS, the ratio of a titanium oxide to the amount of material of the whole film was 77 mol %.

As a result of measuring several spots of the thickness of the carrier transport layer after photolithography, the thickness was up to 50 nm.

After an active-matrix drive type organic EL display device obtained as above was driven, there was no flickering caused by short circuiting but light emission efficiency was remarkably lowered in pixels.

What is claimed is:

1. A method of manufacturing an organic electroluminescence display panel including, on a substrate, first electrodes, a second electrode that is opposed to the first electrodes, barrier ribs partitioning the first electrodes, and a light-emitting medium layer that is sandwiched between the first electrodes and the second electrode and includes at least an organic light-emitting layer and a carrier injection layer that is formed between the first electrodes and the organic light-emitting layer, comprising:
forming a pattern of the first electrodes;
forming, on the first electrodes, the carrier injection layer that comprises a mixture of a hole transport material and a second metal compound, the hole transport material being a first metal compound; and
forming the barrier ribs so as to cover edge portions of the first electrodes of which the pattern is formed and cover at least part of the carrier injection layer.

2. The method of manufacturing an organic electroluminescence display panel according to claim 1, wherein the forming of the barrier ribs includes pattern formation achieved by performing application of a photosensitive resin on the substrate, exposure, development and then rinsing.

3. The method of manufacturing an organic electroluminescence display panel according to claim 1,
wherein the first metal compound is molybdenum oxide,
wherein the second metal compound is a material selected from or a mixture made from any one of molybdenum dioxide, indium oxide, titanium oxide, iridium oxide, tantalum oxide, nickel oxide, tungsten oxide, vanadium oxide, stannous oxide, lead oxide, niobium oxide, aluminum oxide, copper oxide, manganese oxide, praseodymium oxide, chromium oxide, bismuth oxide, calcium oxide, barium oxide, cesium oxide, lithium fluoride, sodium fluoride, zinc selenide, zinc telluride, gallium nitride, gallium indium nitride, magnesium-silver, lithium-aluminum, and lithium-copper, and
wherein a dry film formation method is used.

4. The method of manufacturing an organic electroluminescence display panel according to claim 1, wherein a ratio of the amount of material of the second metal compound to the sum of the amount of material of the hole transport material that is the first metal compound and the amount of material of the second metal compound is 20 mol % or higher and 75 mol % or lower.

5. The method of manufacturing an organic electroluminescence display panel according to claim 1, wherein the organic light-emitting layer is formed by coating organic light-emitting ink obtained by dissolving or dispersing an organic light-emitting material in a solvent.

6. An organic electroluminescence device comprising, on a substrate, first electrodes, a second electrode that is opposed to the first electrodes, barrier ribs partitioning the first electrodes, and a light-emitting medium layer that is sandwiched between the first electrodes and the second electrode and includes at least an organic light-emitting layer and a carrier injection layer that is formed between the first electrodes and the organic light-emitting layer, wherein:
a plurality of the first electrodes are subjected to pattern formation on the substrate;
the carrier injection layer is formed on the first electrodes and comprises a mixture of a hole transport material and a second metal compound, the hole transport material being a first metal compound; and
the barrier ribs cover edge portions of the first electrodes that are subjected to pattern formation and cover a part of the carrier injection layer.

7. The organic electroluminescence device according to claim 6,
wherein the carrier injection layer is continuously formed so as to cover the entire faces on the plurality of the first electrodes and on the substrate.

8. The organic electroluminescence device according to claim 6, wherein a thickness decrease of the carrier injection layer, when the carrier injection layer is immersed in a developer to be used in development of the barrier ribs for three hours, is 10% or lower.

9. The organic electroluminescence device according to claim 6, wherein the thickness of the carrier injection layer covered by the barrier ribs is set to be the same as or thicker than that of the carrier injection layer not covered by the barrier ribs.

10. The organic electroluminescence device according to claim 6,
wherein the first metal compound is molybdenum oxide, and
wherein the second metal compound is a material selected from or a mixture made from any one of molybdenum dioxide, indium oxide, titanium oxide, iridium oxide, tantalum oxide, nickel oxide, tungsten oxide, vanadium oxide, stannous oxide, lead oxide, niobium oxide, aluminum oxide, copper oxide, manganese oxide, praseodymium oxide, chromium oxide, bismuth oxide, calcium oxide, barium oxide, cesium oxide, lithium fluoride, sodium fluoride, zinc selenide, zinc telluride, gallium nitride, gallium indium nitride, magnesium-silver, lithium-aluminum, and lithium-copper.

11. The organic electroluminescence device according to claim 6, wherein a ratio of the amount of material of the second metal compound to the sum of the amount of material of the hole transport material that is the first metal compound and the amount of material of the second metal compound is 20 mol % or higher and 75 mol % or lower.

12. The organic electroluminescence device according to claim 6, wherein the thickness of the carrier injection layer in a light-emitting region on the first electrodes is set to be 20 nm or thicker and 100 nm or thinner.

13. An organic electroluminescence display panel comprising the organic electroluminescence device according to claim 6.

14. An organic electroluminescence display panel comprising the organic electroluminescence device according to claim 7.

15. An organic electroluminescence display panel comprising the organic electroluminescence device according to claim 8.

16. An organic electroluminescence display panel comprising the organic electroluminescence device according to claim 9.

17. An organic electroluminescence display panel comprising the organic electroluminescence device according to claim 10.

18. An organic electroluminescence display panel comprising the organic electroluminescence device according to claim 11.

19. An organic electroluminescence display panel comprising the organic electroluminescence device according to claim 12.
